(19) United States
(12) Patent Application Publication
(10) Pub. No.: US 2023/0042277 A1
(43) Pub. Date: Feb. 9, 2023

(54) SEMICONDUCTOR PROCESSING TOOL AND METHOD FOR PASSIVATION LAYER FORMATION AND REMOVAL

(71) Applicant: Taiwan Semiconductor Manufacturing Company Limited, Hsinchu (TW)

(72) Inventors: Chia-Pang KUO, Taoyuan City (TW); Yao-Min LIU, Taipei (TW); Shu-Cheng CHIN, Hsinchu (TW); Chih-Chien CHI, Hsinchu City (TW); Cheng-Hui WENG, Hsinchu City (TW)

(21) Appl. No.: 17/653,780

(22) Filed: Mar. 7, 2022

Related U.S. Application Data
(60) Provisional application No. 63/260,004, filed on Aug. 6, 2021.

(51) Int. Cl. H01L 21/3065; H01J 37/32; C23C 16/455; H01L 21/677; C23C 16/44

(52) U.S. Cl. CPC H01L 21/30655; C23C 16/4412; C23C 16/45563; H01J 37/32862; H01L 21/67745

(57) ABSTRACT

A semiconductor processing tool performs passivation layer deposition and removal in situ. A transport mechanism included in the semiconductor processing tool transfers a semiconductor structure through different deposition chambers (e.g., without breaking or removing a vacuum environment). Accordingly, the semiconductor processing tool deposits a target layer that is thinner on, or even absent from, a metal layer, such that contact resistance is reduced between a conductive structure formed over the target layer and the metal layer. As a result, electrical performance of a device including the conductive structure is improved. Moreover, because the process is performed in situ (e.g., without breaking or removing the vacuum) in the semiconductor processing tool, production time and risk of impurities in the conductive structure are reduced. As a result, throughput is increased, and chances of spoiled wafers are decreased.

### CROSS REFERENCE TO RELATED APPLICATION

This Patent Application claims priority to U.S. Provisional Pat. Application No. 63/260,004, filed on Aug. 6, 2021, and entitled “SEMICONDUCTOR PROCESSING TOOL, METHODS OF OPERATION, AND SEMICONDUCTOR DEVICE.” The disclosure of the prior Application is considered part of and is incorporated by reference into this Patent Application.

### BACKGROUND

Some electronic devices, such as a processor, a memory device, or another type of electronic device, include a middle end of line (MEOL) region that electrically connects transistors in a front end of line (FEOL) region to a back end of line (BEOL) region. The BEOL region or MEOL region may include a dielectric layer and via plugs formed in the dielectric layer. A plug may include one or more metals for electrical connection.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example semiconductor processing tool described herein.

FIG. 2 is a diagram of an example buffer component described herein for use in the semiconductor processing tool of FIG. 1.

FIG. 3 is a diagram of an example transport mechanism component described herein for use in the semiconductor processing tool of FIG. 1.

FIGS. 4A-4C are diagrams of example plasma components described herein for use in the semiconductor processing tool of FIG. 1.

FIG. 5 is a diagram of an example precursor component described herein for use in the semiconductor processing tool of FIG. 1.

FIGS. 6A-6E are diagrams of an example implementation described herein.

FIG. 7 is a diagram of example components of one or more devices of FIG. 1 described herein.

FIG. 8 is a flowchart of an example process associated with formation and removal of a passivation layer using a semiconductor processing tool described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Many middle end of line (MEOL) and back end of line (BEOL) conductive structures are formed in recesses of oxide layers. However, some metals like copper have high diffusion (or electromigration) rates, which can cause metal atoms to diffuse into surrounding dielectric material. This diffusion results in an increase in resistivity for the MEOL and BEOL structures. Increased resistivity can decrease electrical performance of an electronic device. Moreover, diffusion may result in metal atoms migrating into other MEOL or BEOL layers or even into front end of line (FEOL) layers, such as source or drain interconnects (also referred to as source/drain vias or VDs) and/or gate interconnects (also referred to as gate vias or VGs), which can cause semiconductor device failures and reduced manufacturing yield.

Accordingly, barrier layers (such as titanium nitride (TiN), tantalum nitride (TaN), and/or another type of barrier layer) may be deposited to prevent diffusion. However, the barrier layers increase contact resistance when deposited at an interface between BEOL layers or between an M1 layer and an M0 interconnect, which decreases electrical performance of the electronic device. Additionally, or alternatively, liner layers (such as cobalt (Co), ruthenium (Ru), and/or another type of liner layer) may be deposited to reduce sheet resistance and/or surface roughness of the conductive structure. However, the liner layers also increase contact resistance when deposited at an interface between BEOL layers or between an M1 layer and an M0 interconnect, which decreases electrical performance of the electronic device.

Therefore, a passivation layer may be used to reduce, or even prevent, deposition of barrier and/or liner materials at the interface (e.g., at a bottom surface of the recess in which the conductive structure is formed). However, forming a passivation layer before forming a barrier layer and/or a liner layer, as well as removal of the passivation layer after forming the barrier layer and/or the liner layer, adds time to the production process for the conductive structure. Additionally, formation and removal of the passivation layer occur in separate chambers, which results in higher risk of impurities in the recess when transferring a wafer with the recess between chambers. For example, oxidation of metal exposed at the interface causes imperfections when the passivation layer is deposited such that the barrier layer may be deposited at the interface. As a result, throughput is reduced, and chances of spoiled wafers are increased.

Some implementations described herein provide techniques and apparatuses for using a semiconductor processing tool to perform passivation layer deposition and removal in situ. For example, the semiconductor processing tool may perform a pre-clean operation on a semiconductor structure in a pre-clean processing chamber to clean etch residue and oxides from various surfaces of the semiconductor structure (e.g., sidewalls of a recess and/or a bottom surface of a recess). A transport mechanism included in the semiconductor processing tool may transfer the semiconductor structure to a first deposition chamber (e.g., without breaking or removing the vacuum) in which the semiconductor processing tool deposits a passivation layer at the bottom surface of the recess over a metal layer of the semiconductor structure. The transport mechanism transfers the semiconductor structure to a second deposition chamber (e.g., without breaking or removing the vacuum) in which the semiconductor processing tool deposits a target layer on the sidewalls of the recess. The deposition of the target layer is selective because the passivation layer reduces, or blocks, formation of the target layer over the metal layer in the recess by resisting or preventing adsorption of the material of the target layer. The transport mechanism transfers the semiconductor structure to a removal chamber (e.g., without breaking or removing the vacuum) in which the semiconductor processing tool removes the passivation layer from the metal layer. The target layer remains on the sidewalls of the recess. Accordingly, a conductive structure may subsequently be formed in the recess on the metal layer and on the target layer.

Because the target layer is thinner on, or even absent from, the metal layer, contact resistance is reduced between the conductive structure and the metal layer. As a result, electrical performance of a device including the conductive structure is improved. Moreover, the process is performed in situ (e.g., without breaking or removing the vacuum) in the semiconductor processing tool, which reduces production time and risk of impurities in the conductive structure. As a result, throughput is increased, and chances of spoiled wafers are decreased.

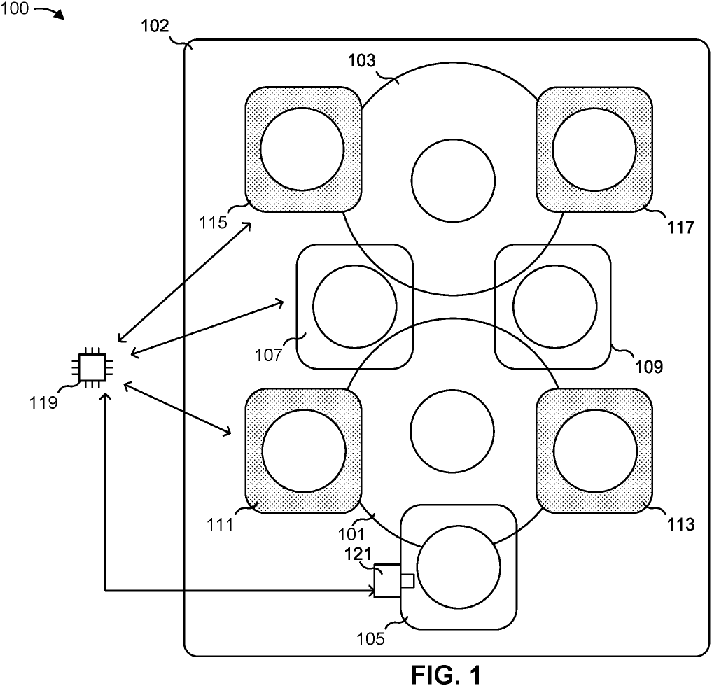

FIG. 1 is a diagram of an example of a deposition system 100 described herein. The deposition system 100 may be configured for use in a semiconductor processing environment such as a semiconductor foundry or a semiconductor fabrication facility.

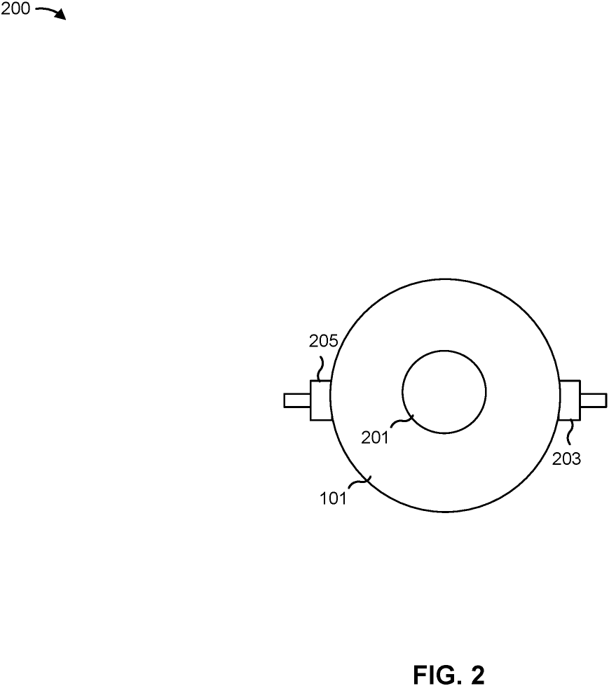

As shown in FIG. 1, the deposition system 100 includes one or more buffers, such as buffer 101 and buffer 103. Buffers 101 and 103 may each include a sealed chamber (e.g., as described in connection with FIG. 2) that receives a wafer between processes performed by the deposition system 100. Buffers 101 and 103 may allow the wafer to outgas after a process performed by the deposition system 100. Additionally, in some implementations, buffers 101 and 103 may provide a purge gas to remove byproducts from a previous process performed by the deposition system 100.

Although described using two buffers, an alternative implementation includes a single buffer in order to conserve space, power, and hardware. Other alternative implementations include additional buffers (e.g., three buffers, four buffers, and so on) in order to further reduce chances of contamination of the wafer between processes.

As shown in FIG. 1, the deposition system 100 includes a mainframe 102 configured to a maintain a vacuum environment as the wafer moves through the deposition system 100. Mainframe 102 may maintain a vacuum environment of at least 10⁻⁷ torr. By selecting a vacuum of at least 10⁻⁷ torr, chances of contamination of the wafer are decreased and/or chances of cross-contamination between processes (e.g., during outgassing) are decreased.

In order to further prevent contamination of the wafer, the deposition system 100 includes one or more transition chambers, such as an initial chamber 105, a first transition chamber 107, and a second transition chamber 109. The initial chamber 105 may receive the wafer and generate a vacuum environment so that the wafer may begin being processed by the deposition system 100. Similar to buffers 101 and 103, the first transition chamber 107 and the second transition chamber 109 may each include a sealed chamber (e.g., as described in connection with FIG. 2) that receives the wafer between processes performed by the deposition system 100. The first transition chamber 107 and the second transition chamber 109 may each maintain a vacuum environment of at least 10⁻⁷ torr. By selecting a vacuum of at least 10⁻⁷ torr, chances of contamination of the wafer are decreased and/or chances of cross-contamination between processes (e.g., during outgassing) are decreased.

Although described using an initial chamber and two transition chambers, an alternative implementation includes a single transition chamber in order to conserve space, power, and hardware. Other alternative implementations include additional transition chambers (e.g., three transition chambers, four transition chambers, and so on) in order to further reduce chances of contamination of the wafer between processes.

As further shown in FIG. 1, the deposition system 100 includes one or more deposition chambers, such as a first chamber 111, a second chamber 113, a third chamber 115, and a fourth chamber 117. The first chamber 111, the second chamber 113, the third chamber 115, and the fourth chamber 117 may each include a sealed chamber that receives and processes the wafer. The first chamber 111, the second chamber 113, the third chamber 115, and the fourth chamber 117 may each maintain a vacuum environment of at least 10⁻¹⁰ torr. By selecting a vacuum of at least 10⁻¹⁰ torr, the wafer may be processed without significant contamination (e.g., less contamination than would degrade performance of a corresponding device by a performance threshold).

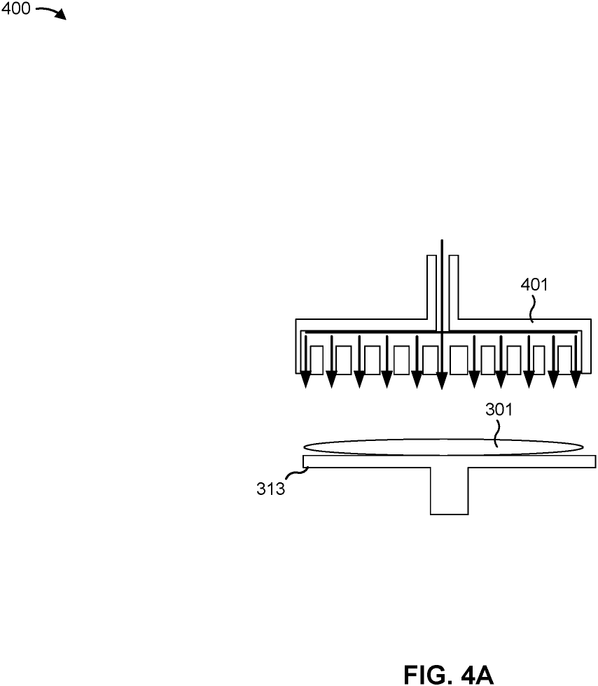

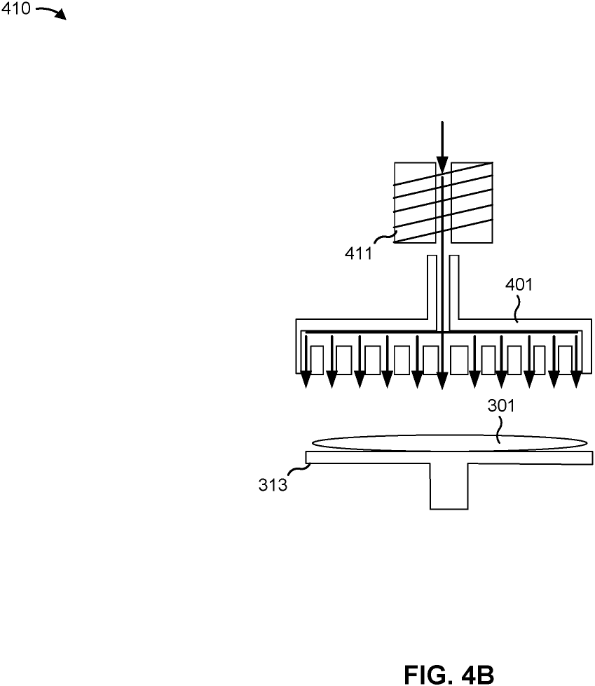

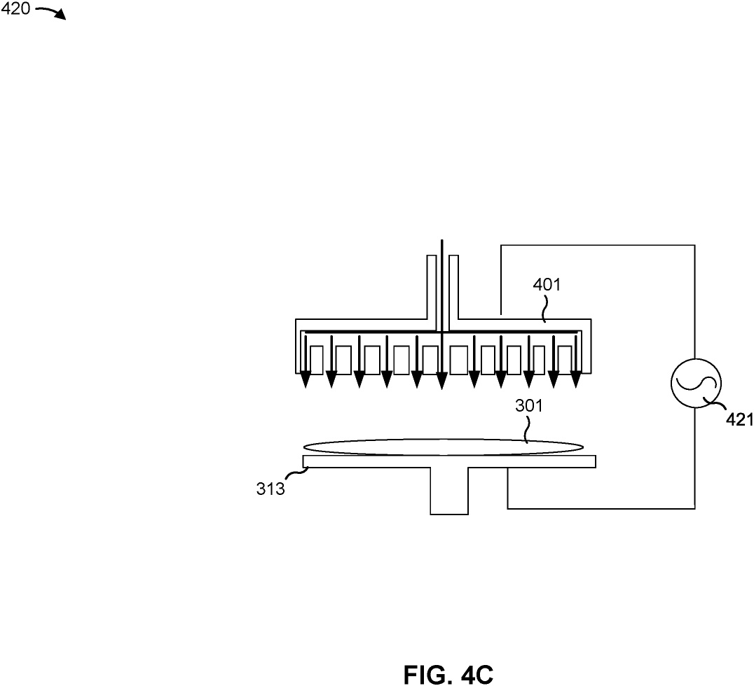

In some implementations, the first chamber 111 performs a cleaning process on the wafer. For example, the first chamber 111 may use a gas, such as hydrogen gas, argon gas, and/or helium gas, delivered via a nozzle (e.g., as described in connection with FIG. 4A), to clean the wafer. Additionally, or alternatively, the first chamber 111 may use a plasma, such as hydrogen plasma, argon plasma, and/or helium plasma, received from a remote plasma system or a direct plasma system (e.g., as described in connection with FIG. 4B or FIG. 4C, respectively), to clean the wafer. As a result, fluorocarbon polymers, such as CFₓ, and/or dielectric composites, such as SiOCFₓ, are removed. Additionally, metal surfaces on the wafer that have oxidized react with the gas and/or the plasma such that the oxygen is vaporized and removed.

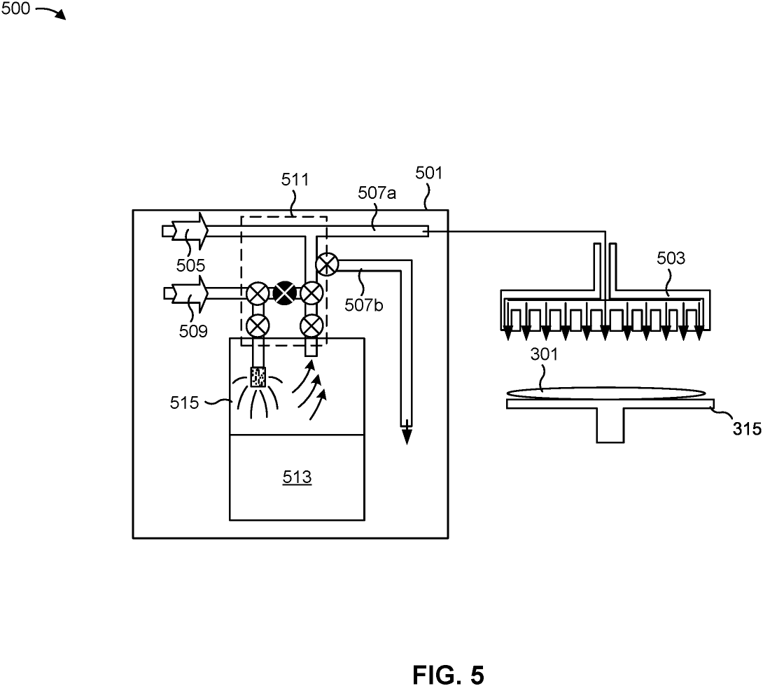

In some implementations, the second chamber 113 deposits a passivation layer on exposed metal surfaces on the wafer. For example, the second chamber 113 may receive precursor materials from an ampoule storage system and inject the precursor materials using a nozzle (e.g., as described in connection with FIG. 5). The passivation layer may include a first anchor group that attaches to metal (e.g., by exhibiting hydrophilic properties) and a second anchor group that repels other materials (e.g., by exhibiting hydrophobic properties). As an alternative, the passivation layer may bond to metal using dipole-dipole bonds or π bonds. Additionally, the passivation layer does not bond to dielectric material or etch stop layer (ESL) materials such that the passivation layer is selectively deposited on exposed metal of the wafer. For example, the passivation layer may include a nitrogen-based head-group, a sulfur-based head-group, a phosphorus-based head-group, a triazole derivative, a thiol, or a thiol derivative. Additionally, or alternatively, the passivation layer may include an alkyne of the form RC=CR' or an alkene of ₜₕe form RC=CR', where R is Hₓ or CₓH_{y.}

In some implementations, the third chamber 115 deposits a target layer on exposed dielectric surfaces on the wafer. For example, the third chamber 115 may receive precursor materials from an ampoule storage system and inject the precursor materials using a nozzle (e.g., as described in connection with FIG. 5). In some implementations, the third chamber 115 may provide a precursor and a reaction gas simultaneously such that the target layer is grown using chemical vapor deposition (CVD). As an alternative, the third chamber 115 may provide the precursor and then perform a purge (e.g., using hydrogen gas, argon gas, and/or helium gas) before providing the reaction gas such that the target layer is grown using atomic layer deposition (ALD). As described above, the passivation layer repels other materials, such as the precursor for the target layer, such that the target layer is not grown on metal surfaces of the wafer. The target layer may include a nitride and/or a metal that would otherwise increase resistance at the metal surfaces of the wafer.

In some implementations, the fourth chamber 117 etches the passivation layer from the wafer. For example, the fourth chamber 117 may use a plasma, such as hydrogen plasma, argon plasma, and/or helium plasma, received from a remote plasma system or a direct plasma system (e.g., as described in connection with FIG. 4B or FIG. 4C, respectively), to etch the passivation layer. As a result, the metal surfaces of the wafer are exposed such that conductive structures (e.g., MEOL and/or BEOL conductive structures) may be formed over the metal surfaces.

Additionally, as shown in FIG. 1, the deposition system 100 may include a controller 119. Although depicted as a single processor to conserve power and space, the controller 119 may alternatively include a plurality of processors in order to increase processing power and reduce latency. The controller 119 may receive signals from sensors associated with the buffer(s), the transition chamber(s), and/or the deposition chamber(s). For example, the controller 119 may receive signals associated with temperatures, pressures, and/or other environmental factors of the buffer(s), the transition chamber(s), and/or the deposition chamber(s). The controller 119 may transmit instructions to hardware associated with the buffer(s), the transition chamber(s), and/or the deposition chamber(s). For example, the controller 119 may transmit instructions to perform cleaning, deposition, and/or etching on the wafer. Although depicted as external, the controller 119 may additionally or alternatively include integrated circuits embedded in one or more other components of the deposition system 100 in order to conserve space.

As further shown in FIG. 1, the initial chamber 105 may include at least one optical sensor 121 (e.g., a camera and/or another collection of pixels configured to generate electrical signals associated with one or more properties of light reflecting off the wafer). Accordingly, the controller 119 may determine one or more parameters for cleaning, deposition, and/or etching of the wafer based on output from the at least one optical sensor 121. In one example, the controller 119 may identify (e.g., using a model, such as a neural network) a level of contamination associated with the wafer and determine a length of time associated with a cleaning process based on the level of contamination. Additionally, or alternatively, the controller 119 may identify a size (e.g., a width or other dimension) of exposed metal areas on the wafer and determine a length of time associated with deposition of the passivation layer based on the size. Additionally, or alternatively, the controller 119 may determine a length of time associated with deposition of the target layer based on the size.

Additionally, or alternatively, the transition chamber 107 and/or the transition chamber 109 may include at least one optical sensor (e.g., a camera and/or another collection of pixels configured to generate electrical signals associated with one or more properties of light reflecting off the wafer). Accordingly, the controller 119 may determine one or more parameters for cleaning, deposition, and/or etching of the wafer based on output from the at least one optical sensor. In one example, the controller 119 may identify (e.g., using a model, such as a neural network) a size (e.g., a width or other dimension) of exposed metal areas on the wafer and determine a length of time associated with deposition and/or etching of the passivation layer based on the size. Additionally, or alternatively, the controller 119 may determine a length of time associated with deposition of the target layer based on the size.

Additionally, or alternatively, the buffer 101 and/or the buffer 103 may include a residual gas analyzer (RGA) configured to detect concentrations, humidity, and/or pressure. Accordingly, the controller 119 may instruct a vacuum pump (e.g., pump 203 as described in connection with FIG. 2) and/or a purge pump (e.g., pump 205 as described in connection with FIG. 2) to operate at a higher speed when pressure, contaminant concentrations, and/or humidity in the buffer 101 and/or the buffer 103 increase.

As indicated above, FIG. 1 is provided as an example. Other examples may differ from what is described with regard to FIG. 1. For example, certain devices and/or components of the deposition system 100 were not shown in FIG. 1 for ease of explanation. Additional devices and/or components relating to the deposition system 100 are described in connection with FIGS. 2-5.

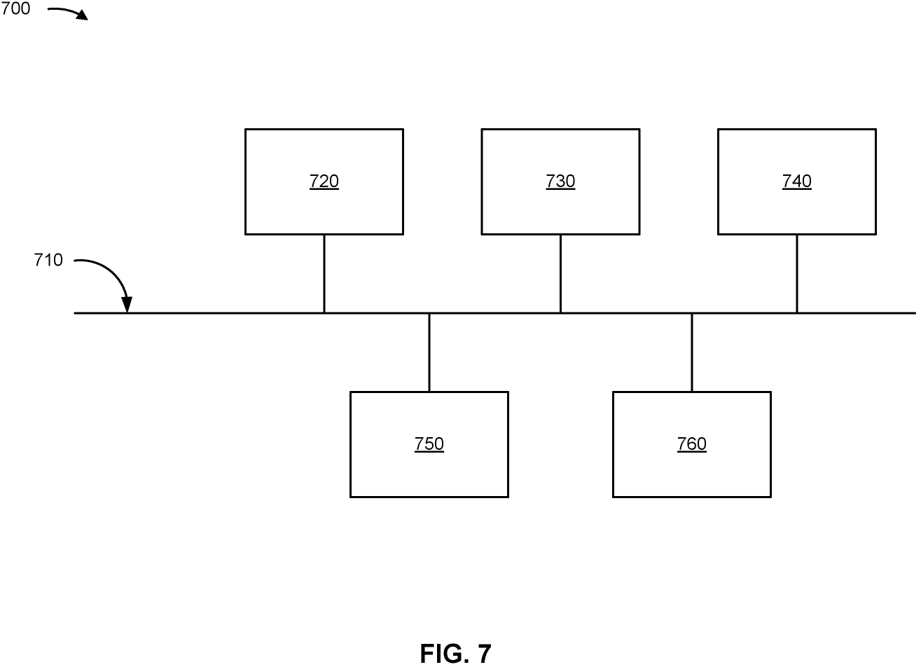

FIG. 2 is a diagram of an example 200 of a buffer component within a deposition tool (e.g., deposition system 100 of FIG. 1). As shown in FIG. 2, example 200 includes a buffer 101 with a stage 201 for supporting a wafer. Additionally, example 200 includes one or more pumps, such as turbomolecular pumps (TMPs) 203 and 205. These devices are described in more detail in connection with FIG. 1 and FIG. 7.

The buffer 101 may allow for outgassing when the wafer is between processes. Accordingly, the buffer 101 may include at least one outlet pump (e.g., the TMP 203) that maintains the vacuum environment in the buffer 101. Additionally, in some implementations, the buffer 101 includes at least one purge pump (e.g., the TMP 205) that introduces a purge gas (e.g., hydrogen gas, argon gas, and/or helium gas) to help the wafer outgas after processing.

As indicated above, FIG. 2 is provided as an example. Other examples may differ from what is described with regard to FIG. 2. The number and arrangement of devices shown in FIG. 2 are provided as an example. In practice, there may be additional devices, fewer devices, different devices, or differently arranged devices than those shown in FIG. 2. Furthermore, two or more devices shown in FIG. 2 may be implemented within a single device, or a single device shown in FIG. 2 may be implemented as multiple, distributed devices. Additionally, or alternatively, a set of devices (e.g., one or more devices) shown in FIG. 2 may perform one or more functions described as being performed by another set of devices shown in FIG. 2.

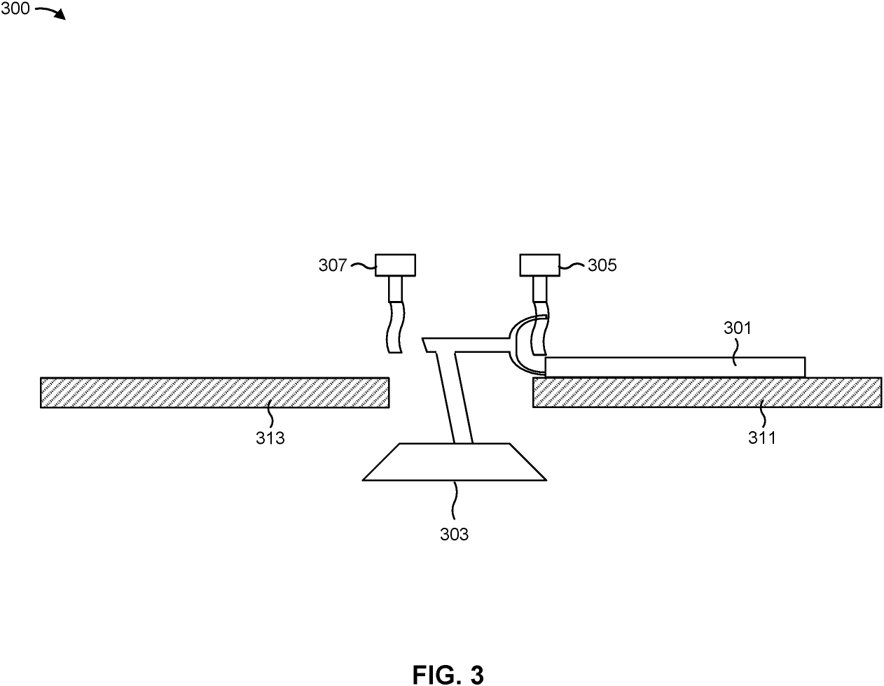

FIG. 3 is a diagram of an example 300 of a transfer mechanism within a deposition tool (e.g., deposition system 100 of FIG. 1). As shown in FIG. 3, example 300 includes a robotic arm 303 configured to grasp, move, and release wafers (e.g., wafer 301). Additionally, example 300 includes one or more pumps, such as air curtain pumps 305 and 307. These devices are described in more detail in connection with FIG. 7.

As shown in FIG. 3, the robotic arm 303 may move the wafer 301 from a buffer (e.g., from a stage 311 of the buffer) into a deposition chamber (e.g., onto a stage 313 of a first chamber). Similarly, the robotic arm 303 may move the wafer 301 from a deposition chamber into the buffer, into a mainframe (e.g., mainframe 102) from a deposition chamber or a buffer, or from the mainframe into a deposition chamber or a buffer. The robotic arm 303 may further transfer the wafer 301 from the buffer or the mainframe into a transition chamber and/or from a transition chamber into the buffer or the mainframe. Although shown using a single robotic arm to conserve power and materials, alternative implementations may include additional robotic arms (e.g., two robotic arms, three robotic arms, and so on) such that the wafer 301 may be moved between different deposition chambers without movement of the robotic arm 303 along a track or other pathway within the deposition system 100.

In some implementations, as shown in FIG. 3, the buffer additionally includes one or more pumps (e.g., the pump 305) configured to provide an air curtain (e.g., of hydrogen, argon, helium, and/or another gas) during transfer of the wafer 301 out of the buffer. As a result, contaminants that entered an environment of the buffer 101 (e.g., from outgassing of the wafer 301) are less likely to enter a deposition chamber (or a transition chamber) when the robotic arm 303 moves the wafer 301. Similarly, the pump 305 may provide the air curtain during transfer of the wafer 301 into the buffer to help prevent contaminants from a deposition chamber (or a transition chamber) from entering the environment of the buffer.

Additionally, or alternatively, the deposition chamber (or the transition chamber) includes one or more pumps (e.g., the pump 307) configured to provide an air curtain (e.g., of hydrogen, argon, helium, and/or another gas) during transfer of the wafer 301 into the deposition chamber (or the transition chamber). As a result, contaminants that entered an environment of the buffer (e.g., from outgassing of the wafer 301) are less likely to enter the deposition chamber (or the transition chamber) when the robotic arm 303 moves the wafer 301. Similarly, the pump 307 may provide the air curtain during transfer of the wafer 301 out of the deposition chamber (or the transition chamber) to help prevent contaminants from the deposition chamber (or the transition chamber) from entering the environment of the buffer.

Similarly, the mainframe may include one or more pumps configured to provide an air curtain (e.g., of hydrogen, argon, helium, and/or another gas) during transfer of the wafer 301 into the mainframe (or out of the mainframe).

As indicated above, FIG. 3 is provided as an example. Other examples may differ from what is described with regard to FIG. 3. The number and arrangement of devices shown in FIG. 3 are provided as an example. In practice, there may be additional devices, fewer devices, different devices, or differently arranged devices than those shown in FIG. 3. Furthermore, two or more devices shown in FIG. 3 may be implemented within a single device, or a single device shown in FIG. 3 may be implemented as multiple, distributed devices. Additionally, or alternatively, a set of devices (e.g., one or more devices) shown in FIG. 3 may perform one or more functions described as being performed by another set of devices shown in FIG. 3.

FIGS. 4A-4C are diagram of examples 400, 410, and 420, respectively, of a deposition chamber within a deposition tool (e.g., deposition system 100 of FIG. 1). As shown in FIGS. 4A-4C, examples 400, 410, and 420 each includes a stage 313 configured to support wafer 301. Additionally, examples 400, 410, and 420 each includes a nozzle 401 configured to provide gas and/or plasma into the deposition chamber. These devices are described in more detail in connection with FIG. 1.

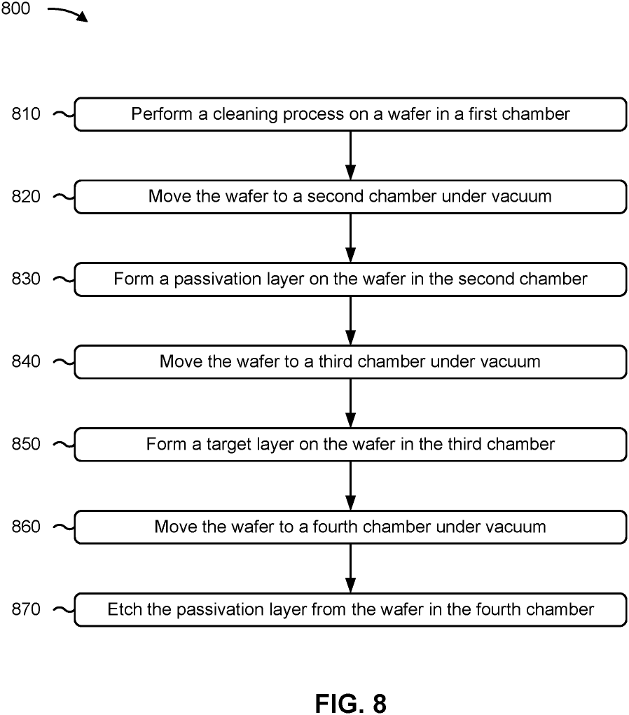

In example 400 of FIG. 4A, the nozzle 401 provides gas (e.g., from a storage system) into the deposition chamber. As further shown in FIG. 4B, example 410 includes a remote plasma system 411 such that the nozzle 401 provides plasma into the deposition chamber. As further shown in FIG. 4C, example 420 includes a direct plasma system 421 such that the nozzle 401 provides gas (e.g., from a storage system) into the deposition chamber that is energized and turned into plasma by the direct plasma system 421. For example, the direct plasma system 421 may include an electric system that generates a large voltage differential across the deposition chamber to energize the gas provided by the nozzle 401. Accordingly, examples 400, 410, and 420 may be used to clean wafer 301 and to selectively etch a passivation layer, as described in connection with FIG. 1 and FIG. 8.

As indicated above, FIGS. 4A-4C are provided as examples. Other examples may differ from what is described with regard to FIGS. 4A-4C. The numbers and arrangements of devices shown in FIGS. 4A-4C are provided as examples. In practice, there may be additional devices, fewer devices, different devices, or differently arranged devices than those shown in FIGS. 4A-4C. Furthermore, two or more devices shown in FIGS. 4A-4C may be implemented within a single device, or a single device shown in FIGS. 4A-4C may be implemented as multiple, distributed devices. Additionally, or alternatively, a set of devices (e.g., one or more devices) shown in FIGS. 4A-4C may perform one or more functions described as being performed by another set of devices shown in FIGS. 4A-4C.

FIG. 5 is a diagram of an example 500 of a deposition chamber within a deposition tool (e.g., deposition system 100 of FIG. 1). As shown in FIG. 5, example 500 includes an ampoule system 501 configured to generate precursor materials into the deposition chamber. Additionally, example 500 includes a stage 315 configured to support wafer 301 and a nozzle 503 configured to provide the precursor materials into the deposition chamber. These devices are described in more detail in connection with FIG. 1.

As shown in FIG. 5, the ampoule system 501 may include a supply 505 configured to provide a purge gas and/or a reaction gas to the nozzle 503 through a gas line 507a. For example, the purge gas may be used after CVD or during ALD. Similarly, the reaction gas may be used in CVD or ALD.

As further shown in FIG. 5, the ampoule system 501 may include a supply 509 configured to provide a carrier gas to the nozzle 503 through the gas line 507a. For example, the carrier gas may include precursor materials generated using a hotcan 511. For example, the hotcan 511 may mix the carrier gas with precursor materials that are included in liquid or solid form in a storage 513 and vaporized in a chamber 515.

Accordingly, the nozzle 503 may deliver precursor materials and reaction gas for CVD and ALD to form a passivation layer and a target layer, as described in connection with FIG. 1 and FIG. 8. A gas line 507b may provide an outlet to release pressure or to remove excess precursor materials and/or carrier gas during a purge.

As indicated above, FIG. 5 is provided as an example. Other examples may differ from what is described with regard to FIG. 5. The number and arrangement of devices shown in FIG. 5 are provided as an example. In practice, there may be additional devices, fewer devices, different devices, or differently arranged devices than those shown in FIG. 5. Furthermore, two or more devices shown in FIG. 5 may be implemented within a single device, or a single device shown in FIG. 5 may be implemented as multiple, distributed devices. Additionally, or alternatively, a set of devices (e.g., one or more devices) shown in FIG. 5 may perform one or more functions described as being performed by another set of devices shown in FIG. 5.

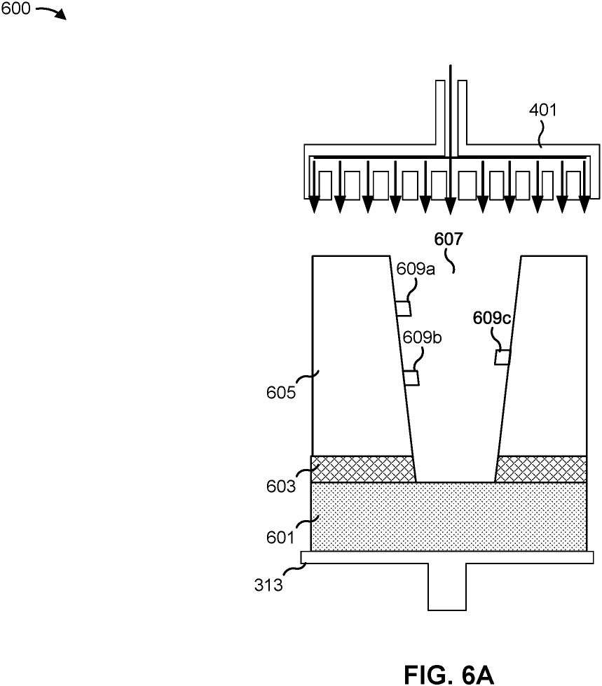

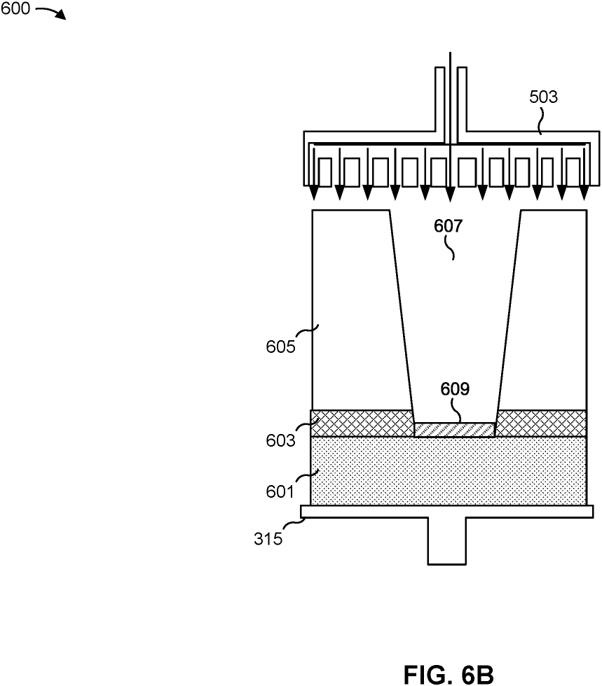

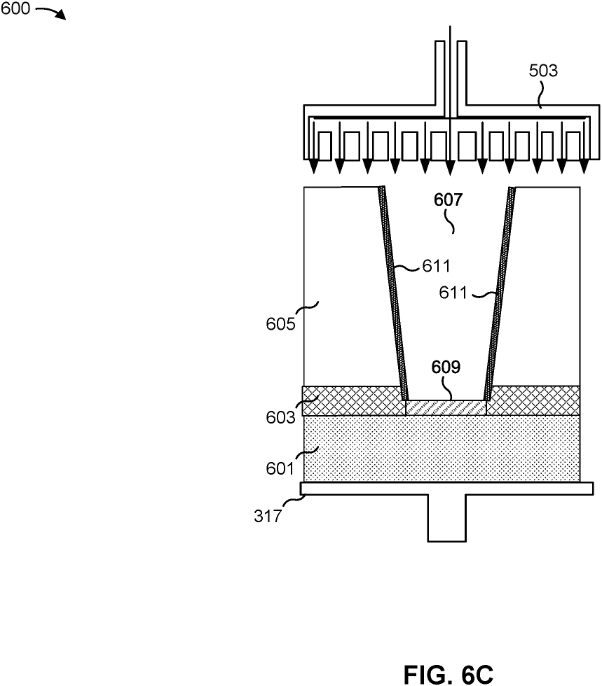

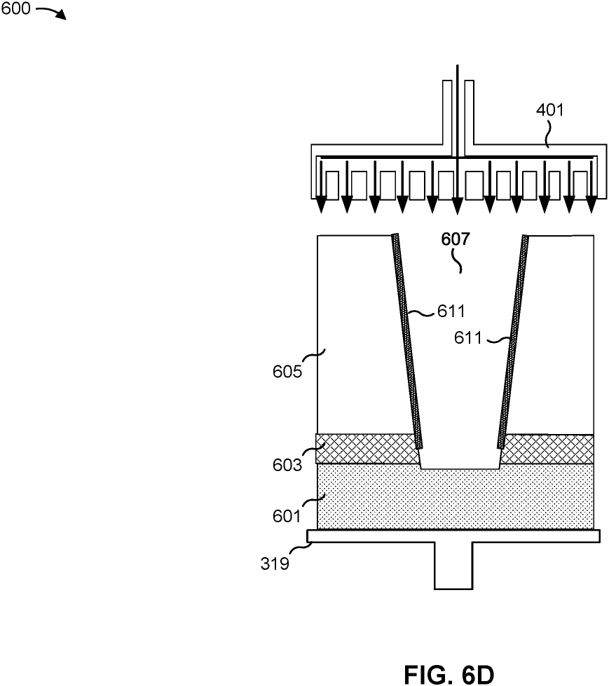

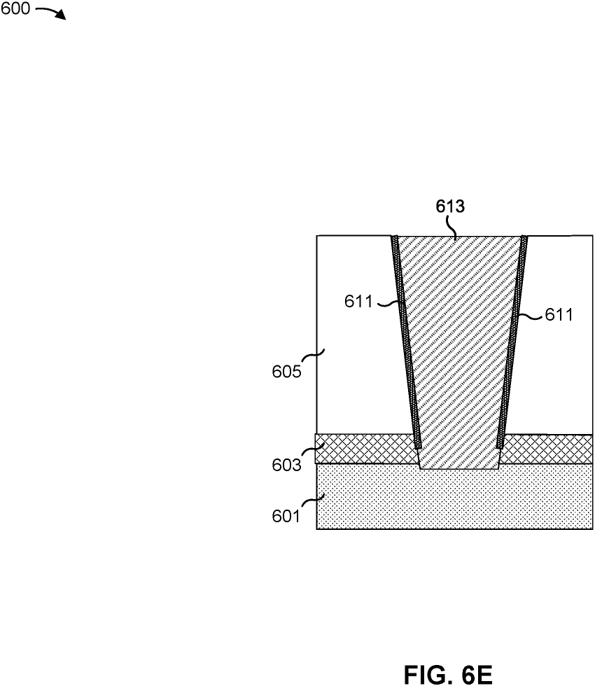

FIGS. 6A-6E are diagrams of an example implementation 600 described herein. Example implementation 600 may be an example process for forming and removing a passivation layer 609 using a deposition tool (e.g., deposition system 100 of FIG. 1).

As shown in FIG. 6A, a wafer on a stage 313 in a first chamber (e.g., first chamber 111) may include a metal layer 601 (e.g., a copper layer for a BEOL or a ruthenium layer for an MEOL), at least one ESL 603, and a dielectric layer 605. The dielectric layer 605 may include silicon oxycarbide (SiOC). The ESL 603 may include aluminum oxide (Al₂O₃), aluminum nitride (AlN), silicon nitride (SiN), silicon oxynitride (SiOₓN_{y}), aluminum oxynitride (AlON), and/or a silicon oxide (SiOₓ). In some implementations, the ESL 603 includes a plurality of ESL layers stacked together to function as an etch stop.

The dielectric layer 605 includes a recessed portion 607 for formation of a conductive structure above the metal layer 601. Additionally, the wafer includes contaminants 609a, 609b, and 609c (e.g., fluorocarbon polymers and/or dielectric composites) that are vaporized via gas and/or plasma from nozzle 401. Additionally, oxygen that reacted with the metal layer 601 may be vaporized and removed using the gas and/or plasma from nozzle 401.

Afterwards, the wafer may be moved to a stage 315 in a second chamber (e.g., second chamber 113). For example, the wafer may be moved through mainframe 102 and/or buffer 101 using transport mechanism 303 such that the vacuum environment around the wafer is not disturbed. As shown in FIG. 6B, nozzle 503 may provide precursor materials and reaction gas such that passivation layer 609 is formed. The passivation layer 609 is selectively grown on an exposed portion of the metal layer 601 and not on the dielectric layer 605 or the ESL 603. The passivation layer 609 may be grown to a depth in a range from 0.6 nanometers (nm) to 3.0 nm. By selecting a depth of at least 0.6 nm, the passivation layer 609 is thick enough to prevent deposition of the target layer 611 on the passivation layer 609. For example, 0.6 nm may be sufficient when the passivation layer 609 includes an alkyne of the form RC=CR' or an alkene of the form RC=CR', where R is Hₓ or CₓH_{y.} When the passivation layer 609 includes a nitrogen-based head-group or another composition, 1.0 nm may be thick enough to prevent deposition of the target layer 611 on the passivation layer 609. By selecting a depth of no more than 3.0 nm, the passivation layer 609 is thin enough to selectively etch without damaging the target layer 611.

Afterwards, the wafer may be moved to a stage 317 in a third chamber (e.g., third chamber 115). For example, the wafer may be moved through the mainframe 102, the buffer 101, and/or transition chamber 107 using the transport mechanism 303 such that the vacuum environment around the wafer is not disturbed. As shown in FIG. 6C, nozzle 503 may provide precursor materials and reaction gas such that target layer 611 is formed. The target layer 611 is selectively grown on the dielectric layer 605 and the ESL 603 and not on the passivation layer 609.

Afterwards, the wafer may be moved to a stage 319 in a fourth chamber (e.g., fourth chamber 117). For example, the wafer may be moved through the mainframe 102 and/or buffer 103 using transport mechanism 303 such that the vacuum environment around the wafer is not disturbed. As shown in FIG. 6D, the passivation layer 609 is selectively etched via plasma from nozzle 401. As shown in FIG. 6D, the target layer 611 is absent from a portion of sidewalls of the recessed portion 607 approximately equal to the depth of the passivation layer 609.

The wafer may be transferred through the mainframe 102, the buffer 103, and/or transition chamber 109 such that the conductive structure 613 may be deposited in the recessed portion 607, as shown in FIG. 6E. For example, copper may be flowed into the recessed portion 607 to form the conductive structure 613 above the metal layer 601. In FIGS. Figs, 6A-6E, the formed structure has a single damascene structure with a via. In other implementations, the formed structure may have a dual damascene with a lower via and an upper line after a chemical mechanical polishing (CMP).

By using techniques as described in connection with FIGS. 6A-6E, the target layer 611 is thinner on, or even absent from, the metal layer 601, such that contact resistance is reduced between a conductive structure formed over the target layer 611 and the metal layer 601. As a result, electrical performance of a device including the conductive structure is improved. Moreover, because process is performed in situ (e.g., without breaking or removing the vacuum), production time and risk of impurities in the conductive structure are reduced. As a result, throughput is increased, and chances of spoiled wafers are decreased.

As indicated above, FIGS. 6A-6E are provided as an example. Other examples may differ from what is described with regard to FIGS. 6A-6E.

FIG. 7 is a diagram of example components of a device 700, which may correspond to a controller (e.g., controller 119), a sensor (e.g., optical sensor 121), a transport mechanism (e.g., transport mechanism 303), and/or a pump (e.g., pump 203, pump 205, pump 305, and/or pump 307). In some implementations, a controller, a sensor, a transport mechanism, and/or a pump include one or more devices 700 and/or one or more components of device 700. As shown in FIG. 7, device 700 may include a bus 710, a processor 720, a memory 730, an input component 740, an output component 750, and a communication component 7 60.

Bus 710 includes one or more components that enable wired and/or wireless communication among the components of device 700. Bus 710 may couple together two or more components of FIG. 7, such as via operative coupling, communicative coupling, electronic coupling, and/or electric coupling. Processor 720 includes a central processing unit, a graphics processing unit, a microprocessor, a controller, a microcontroller, a digital signal processor, a field-programmable gate array, an application-specific integrated circuit, and/or another type of processing component. Processor 720 is implemented in hardware, firmware, or a combination of hardware and software. In some implementations, processor 720 includes one or more processors capable of being programmed to perform one or more operations or processes described elsewhere herein.

Memory 730 includes volatile and/or nonvolatile memory. For example, memory 730 may include random access memory (RAM), read only memory (ROM), a hard disk drive, and/or another type of memory (e.g., a flash memory, a magnetic memory, and/or an optical memory). Memory 730 may include internal memory (e.g., RAM, ROM, or a hard disk drive) and/or removable memory (e.g., removable via a universal serial bus connection). Memory 730 may be a non-transitory computer-readable medium. Memory 730 stores information, instructions, and/or software (e.g., one or more software applications) related to the operation of device 700. In some implementations, memory 730 includes one or more memories that are coupled to one or more processors (e.g., processor 720), such as via bus 710.

Input component 740 enables device 700 to receive input, such as user input and/or sensed input. For example, input component 740 may include a touch screen, a keyboard, a keypad, a mouse, a button, a microphone, a switch, a sensor, a global positioning system sensor, an accelerometer, a gyroscope, and/or an actuator. Output component 750 enables device 700 to provide output, such as via a display, a speaker, and/or a light-emitting diode. Communication component 7 6 0 enables device 700 to communicate with other devices via a wired connection and/or a wireless connection. For example, communication component 76 0 may include a receiver, a transmitter, a transceiver, a modem, a network interface card, and/or an antenna.

Device 700 may perform one or more operations or processes described herein. For example, a non-transitory computer-readable medium (e.g., memory 730) may store a set of instructions (e.g., one or more instructions or code) for execution by processor 720. Processor 720 may execute the set of instructions to perform one or more operations or processes described herein. In some implementations, execution of the set of instructions, by one or more processors 720, causes the one or more processors 720 and/or the device 700 to perform one or more operations or processes described herein. In some implementations, hardwired circuitry is used instead of or in combination with the instructions to perform one or more operations or processes described herein. Additionally, or alternatively, processor 720 may be configured to perform one or more operations or processes described herein. Thus, implementations described herein are not limited to any specific combination of hardware circuitry and software.

The number and arrangement of components shown in FIG. 7 are provided as an example. Device 700 may include additional components, fewer components, different components, or differently arranged components than those shown in FIG. 7. Additionally, or alternatively, a set of components (e.g., one or more components) of device 700 may perform one or more functions described as being performed by another set of components of device 700.

FIG. 8 is a flowchart of an example process 800 associated with passivation layer formation and removal. In some implementations, one or more process blocks of FIG. 8 are performed by a device (e.g., deposition system 100 of FIG. 1). In some implementations, one or more process blocks of FIG. 8 are performed by another device or a group of devices separate from or including the device, such as a controller (e.g., controller 119), a sensor (e.g., optical sensor 121), a transport mechanism (e.g., transport mechanism 303), and/or a pump (e.g., pump 203, pump 205, pump 305, and/or pump 307). Additionally, or alternatively, one or more process blocks of FIG. 8 may be performed by one or more components of device 700, such as processor 720, memory 730, input component 740, output component 750, and/or communication component 760.

In some aspects, a wafer may be provided into a mainframe of a system, where the mainframe is configured to maintain a vacuum environment. For example, the transport mechanism 303 may move a wafer into the mainframe 102.

Accordingly, as shown in FIG. 8, process 800 may include performing a cleaning process on a wafer in a first chamber (block 810). For example, the controller 119 may perform a cleaning process on a wafer 301 in a first chamber 111, as described herein.

As further shown in FIG. 8, process 800 may include moving the wafer to a second chamber of the system in the mainframe under vacuum (block 82 0). For example, the transport mechanism 303 may move the wafer to a second chamber 113 of the system in the mainframe 102 under vacuum, as described herein.

As further shown in FIG. 8, process 800 may include forming a passivation layer on the wafer in the second chamber (block 830). For example, the controller 119 may form a passivation layer 609 on the wafer 301 in the second chamber 113, as described herein.

As further shown in FIG. 8, process 800 may include moving the wafer to a third chamber of the system in the mainframe under vacuum (block 840). For example, the transport mechanism 303 may move the wafer 301 to a third chamber 115 of the system in the mainframe 102 under vacuum, as described herein.

As further shown in FIG. 8, process 800 may include forming a target layer on the wafer in the third chamber (block 850). For example, the controller 119 may form a target layer 611 on the wafer 301 in the third chamber 115, as described herein.

As further shown in FIG. 8, process 800 may include moving the wafer to a fourth chamber of the system in the mainframe under vacuum (block 860). For example, the transport mechanism 303 may move the wafer 301 to a fourth chamber 117 of the system in the mainframe 102 under vacuum, as described herein.

As further shown in FIG. 8, process 800 may include etching the passivation layer from the wafer in the fourth chamber (block 870). For example, the controller 119 may etch the passivation layer 609 from the wafer 301 in the fourth chamber 117, as described herein.

Process 800 may include additional implementations, such as any single implementation or any combination of implementations described below and/or in connection with one or more other processes described elsewhere herein.

In a first implementation, the cleaning process uses a hydrogen gas, argon gas, helium gas, hydrogen plasma, argon plasma, helium plasma, or a combination thereof.

In a second implementation, alone or in combination with the first implementation, the target layer 611 includes a nitride, a metal, or a combination thereof.

In a third implementation, alone or in combination with one or more of the first and second implementations, the passivation layer 609 includes a nitrogen-based head-group, a sulfur-based head-group, a phosphorus-based head-group, a triazole derivative, a thiol, or a thiol derivative.

In a fourth implementation, alone or in combination with one or more of the first through third implementations, the passivation layer 609 includes an alkyne of the form RC=CR' or an alkene of the RC=CR', wherein R is H_{X} or CₓH_{y.}

In a fifth implementation, alone or in combination with one or more of the first through fourth implementations, the wafer 301 has a metal layer 601, at least one ESL 603, and a dielectric layer 605, and the dielectric layer 605 includes a recessed portion 607 such that the metal layer 601 is at least partially exposed.

In a sixth implementation, alone or in combination with one or more of the first through fifth implementations, the passivation layer 609 is formed on an exposed portion of the metal layer 601 and is formed without disturbing the vacuum environment surrounding the wafer 301.

In a seventh implementation, alone or in combination with one or more of the first through sixth implementations, the passivation layer 609 prevents formation of the target layer 611 on a bottom surface of the recessed portion 607, and the target layer 611 is formed without disturbing the vacuum environment surrounding the wafer 301.

In an eighth implementation, alone or in combination with one or more of the first through seventh implementations, the passivation layer 609 is etched without disturbing the vacuum environment surrounding the wafer 301.

In a ninth implementation, alone or in combination with one or more of the first through eighth implementations, process 800 further includes scanning the wafer 301 to determine one or more parameters associated with cleaning the wafer 301, forming the passivation layer 609, forming the target layer 611, or etching the passivation layer 609.

In a tenth implementation, alone or in combination with one or more of the first through ninth implementations, etching the passivation layer 609 includes plasma striking, thermal annealing, or a combination thereof.

In an eleventh implementation, alone or in combination with one or more of the first through tenth implementations, cleaning the wafer 301 reduces metal oxide at the exposed portion of the metal layer 601.

In a twelfth implementation, alone or in combination with one or more of the first through eleventh implementations, the passivation layer 609 includes a dry self-assembling monolayer.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

In this way, a semiconductor processing tool performs passivation layer deposition and removal in situ. A transport mechanism included in the semiconductor processing tool transfers a semiconductor structure through different deposition chambers (e.g., without breaking or removing a vacuum environment). Accordingly, the semiconductor processing tool deposits a target layer that is thinner on, or even absent from, a metal layer, such that contact resistance is reduced between a conductive structure formed over the target layer and the metal layer. As a result, electrical performance of a device including the conductive structure is improved. Moreover, because the process is performed in situ (e.g., without breaking or removing the vacuum) in the semiconductor processing tool, production time and risk of impurities in the conductive structure are reduced. As a result, throughput is increased, and chances of spoiled wafers are decreased.

As described in greater detail above, some implementations described herein provide a system. The system includes a first chamber configured to perform a cleaning process on a wafer. The system further includes a second chamber configured to deposit a passivation layer on the wafer. The system includes a third chamber configured to deposit a target layer on the wafer. The system further includes a fourth chamber configured to etch the passivation layer from the wafer. The system includes a transport mechanism configured to move the wafer between the first chamber, the second chamber, the third chamber, and the fourth chamber. The system further includes a mainframe enclosing the first chamber, the second chamber, the third chamber, the fourth chamber, and the transport mechanism and configured to maintain a vacuum environment during movement of the wafer between the first chamber, the second chamber, the third chamber, and the fourth chamber.

As described in greater detail above, some implementations described herein provide a method. The method includes providing a wafer into a mainframe of a system, where the mainframe is configured to maintain a vacuum environment. The method further includes performing a cleaning process on a wafer in a first chamber of the system. The method includes moving the wafer to a second chamber of the system in the mainframe under vacuum. The method further includes forming a passivation layer on the wafer in the second chamber. The method includes moving the wafer to a third chamber of the system in the mainframe under vacuum. The method further includes forming a target layer on the wafer in the third chamber. The method includes moving the wafer to a fourth chamber of the system in the mainframe under vacuum. The method further includes etching the passivation layer from the wafer in the fourth chamber.

As described in greater detail above, some implementations described herein provide a method. The method includes cleaning a wafer having a metal layer, at least one etch stop layer (ESL), and a dielectric layer, wherein the dielectric layer includes a recessed portion such that the metal layer is at least partially exposed. The method further includes forming a passivation layer on an exposed portion of the metal layer, wherein the passivation layer is formed without disturbing a vacuum environment surrounding the wafer. The method includes forming a target layer on sidewalls of the recessed portion, wherein the passivation layer prevents formation of the target layer on a bottom surface of the recessed portion, and wherein the target layer is formed without disturbing the vacuum environment surrounding the wafer. The method further includes etching the passivation layer from the wafer, wherein the passivation layer is etched without disturbing the vacuum environment surrounding the wafer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A system, comprising:
a first chamber configured to perform a cleaning process on a wafer;
a second chamber configured to deposit a passivation layer on the wafer;
a third chamber configured to deposit a target layer on the wafer;
a fourth chamber configured to etch the passivation layer from the wafer;
a transport mechanism configured to move the wafer between the first chamber, the second chamber, the third chamber, and the fourth chamber; and
a mainframe enclosing the first chamber, the second chamber, the third chamber, the fourth chamber, and the transport mechanism and configured to maintain a vacuum environment during movement of the wafer between the first chamber, the second chamber, the third chamber, and the fourth chamber.

2. The system of claim 1, further comprising:
at least one pump configured to provide an air curtain between the mainframe and one or more of the first chamber, the second chamber, the third chamber, or the fourth chamber.

3. The system of claim 2, wherein the at least one pump and the mainframe are configured to maintain the vacuum environment at least at 10⁻⁷ torr.

4. The system of claim 1, wherein the transport mechanism comprises one or more robotic arms configured to grasp, move, and release the wafer.

5. The system of claim 1, wherein the first chamber, the second chamber, the third chamber, and the fourth chamber configured to maintain a vacuum at least at 10⁻¹⁰ torr.

6. The system of claim 1, wherein the first chamber, the fourth chamber, or a combination thereof include a nozzle configured to inject gas.

7. The system of claim 1, wherein the first chamber includes a nozzle configured to inject gas.

8. The system of claim 1, wherein the first chamber, the fourth chamber, or a combination thereof include a remote plasma system configured to inject plasma.

9. The system of claim 1, wherein the first chamber, the fourth chamber, or a combination thereof receive plasma from a direct plasma system configured to generate plasma.

10. The system of claim 1, wherein the second chamber, the third chamber, or a combination thereof receive precursor materials from an ampoule storage system and a nozzle configured to inject the precursor materials.

11. A method, comprising:
providing a wafer into a mainframe of a system, wherein the mainframe is configured to maintain a vacuum environment;
performing a cleaning process on the wafer in a first chamber of the system;
moving the wafer to a second chamber of the system in the mainframe under vacuum ;
forming a passivation layer on the wafer in the second chamber;
moving the wafer to a third chamber of the system in the mainframe under vacuum;
forming a target layer on the wafer in the third chamber;
moving the wafer to a fourth chamber of the system in the mainframe under vacuum ; and
etching the passivation layer from the wafer in the fourth chamber.

12. The method of claim 11, wherein the cleaning process uses a hydrogen gas, argon gas, helium gas, hydrogen plasma, argon plasma, helium plasma, or a combination thereof.

13. The method of claim 11, wherein the target layer comprises a nitride, a metal, or a combination thereof.

14. The method of claim 11, wherein the passivation layer comprises a nitrogen-based head-group, a sulfur-based head-group, a phosphorus-based head-group, a triazole derivative, a thiol, or a thiol derivative.

15. The method of claim 11, wherein the passivation layer comprises an alkyne of the form RC=CR' or an alkene of the RC=CR', wherein R is Hₓ or CₓH_{y}.

16. A method, comprising:
cleaning a wafer having a metal layer, at least one etch stop layer (ESL), and a dielectric layer, wherein the dielectric layer includes a recessed portion such that the metal layer is at least partially exposed;
forming a passivation layer on an exposed portion of the metal layer, wherein the passivation layer is formed without disturbing a vacuum environment surrounding the wafer;
forming a target layer on sidewalls of the recessed portion, wherein the passivation layer prevents formation of the target layer on a bottom surface of the recessed portion, wherein the target layer is formed without disturbing the vacuum environment surrounding the wafer; and
etching the passivation layer from the wafer, wherein the passivation layer is etched without disturbing the vacuum environment surrounding the wafer.

17. The method of claim 16, further comprising:
scanning the wafer to determine one or more parameters associated with cleaning the wafer, forming the passivation layer, forming the target layer, or etching the passivation layer.

18. The method of claim 16, wherein etching the passivation layer includes plasma striking, thermal annealing, or a combination thereof.

19. The method of claim 16, wherein cleaning the wafer reduces metal oxide at the exposed portion of the metal layer.

20. The method of claim 16, wherein the passivation layer comprises a dry self-assembling monolayer.
